(19) United States
(12) Patent Application Publication
(10) Pub. No.: US 2011/0286062 A1
(43) Pub. Date: Nov. 24, 2011

(54) Image processing apparatus, image processing method, and computer program product

(75) Inventor: Akiyoshi Nakai, Kanagawa (JP)

(73) Assignee: Ricoh Company, Limited, Tokyo (JP)

(21) Appl. No.: 13/067,294

(22) Filed: May 23, 2011

(30) Foreign Application Priority Data
May 24, 2010 (JP) 2010-118122
May 10, 2011 (JP) 2011-105528

(51) Int. Cl. G03F 3/08

(52) U.S. Cl. 358/518

(57) ABSTRACT

An image processing apparatus that generates color-reduced image data containing fewer colors than the number of colors in input image data includes a hue identifying unit that identifies to which hue region of a color space a hue of each pixel in the image data belongs; an output-color correspondence determining unit that determines correspondence between the hue regions and respective output colors of the color-reduced image data; and a color-reduced image data generating unit that converts a color of each pixel in the image data to an output color corresponding to the hue region, wherein the output-color correspondence determining unit associates, as the output colors, colors that are generated by mixing mutually-different color materials that are fewer in number than the output colors, at different mixing ratios with the respective hue regions, the color materials forming a representative color that determines a range of the output colors.

### CROSS-REFERENCE TO RELATED APPLICATIONS

The present application claims priority to and incorporates by reference the entire contents of Japanese Patent Application No. 2010-118122 filed in Japan on May 24, 2010 and Japanese Patent Application No. 2011-105528 filed in Japan on May 10, 2011.

### BACKGROUND OF THE INVENTION

1. Field of the Invention

The present invention relates to an image processing apparatus, an image processing method, and a computer program product.

2. Description of the Related Art

In general, an image forming apparatus, such as a copying machine, handles an original as a collection of pixels each having a tiny area, and represents a color of each pixel by values (tone values) each indicating the intensity (luminance) of any of color components C (cyan), M (magenta), and Y (yellow) that are the three primary colors of pigment, in order to output an image, in which the color tinge of the original is accurately reproduced, through printing or the like.

In recent years, image forming apparatuses have also been required to have various functions, such as a two-color copying function of converting an original to an image (a color-reduced image) so that colors in the image are reduced to an achromatic color and a chromatic color, e.g., red and black, for output, by processing the tone values of the above color components depending on user's needs.

As a method of generating such a color-reduced image, the following conventional method has been known: when, for example, a color-reduced image formed of red and black is to be generated, a color space is divided into two hue regions so that colors in each of the hue regions are converted to either red or black; a hue region to which each pixel contained in an input image (hereinafter, the pixel is described as an “input pixel”) belongs is identified; and a color of the input pixel is converted to either red or black depending on the identified hue region.

To meet more detailed needs of users, the following method has been known: when a color-reduced image formed of one chromatic color and one achromatic color is to be generated, the chromatic color is handled as a secondary color that is made by mixing at least two color materials; and a mixing ratio of these color materials is adjusted by an instruction, which is sent by a user through an input device of an image forming apparatus, so that the chromatic color can be adjusted to a color tone desired by the user (see Japanese Patent Application Laid-open No. 2007-13724).

Furthermore, the following method has been known: when a color-reduced image formed of one chromatic color and one achromatic color is to be generated, the luminance that each input pixel is to have after color conversion is changed depending on a hue angle between a color that is located in the center of a hue region in which colors are converted to the chromatic color and a color of each input pixel in a color space, or depending on color saturation of the color of each pixel, in order that a difference between colors contained in the input image can be represented by a tone difference of the chromatic color in the color-reduced image (see Japanese Patent Application Laid-open No. H8-84268).

However, with the conventional image forming apparatuses, the number of colors contained in a color-reduced image (hereinafter, the colors are described as “output colors”) is always two in every case, so that a capability (representational ability) of representing, in a color-reduced image, a difference between colors contained in an input image is limited. Furthermore, in the method disclosed in Japanese Patent Application Laid-open No. H8-84268 in which a secondary color is used as a chromatic color that forms a color-reduced image, even though only two colors, i.e., red and black, are represented on the color-reduced image, a total of three color materials, such as Y (yellow) and M (magenta) for generating red and K (black) for generating black, are used. That is, the number of colors contained in the color-reduced image is smaller than the number of the color materials to be consumed, so that the representational ability worthy of the number of the color materials cannot be achieved.

### SUMMARY OF THE INVENTION

It is an object of the present invention to at least partially solve the problems in the conventional technology.

An image processing apparatus that generates color-reduced image data that contains fewer colors than the number of colors contained in input image data, the image processing apparatus including: a hue identifying unit that identifies to which hue region among a plurality of hue regions, which are provided by dividing a color space by hues, a hue of each pixel contained in the image data belongs; an output-color correspondence determining unit that determines correspondence between the hue regions and respective output colors that are used for generating the color-reduced image data; and a color-reduced image data generating unit that converts a color of each pixel contained in the image data to an output color corresponding to the hue region identified by the hue identifying unit, wherein the output-color correspondence determining unit associates, as the output colors, colors that are generated by mixing mutually-different color materials at different mixing ratios with the respective hue regions, the color materials forming a representative color that determines a hue range of the output colors and being fewer than a number of the output colors.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a block diagram of a hardware configuration of an image processing apparatus according to an embodiment of the present invention;

FIG. 2 is a block diagram of a functional configuration of the image processing apparatus according to the embodiment;

FIG. 3 is a diagram illustrating a setting example of hue regions in a hue space;

FIG. 4 is a diagram illustrating an example of a data structure of an output color profile stored in an output color profile storage unit;

FIG. 5 is a flowchart of a procedure of image processing according to the embodiment;

FIG. 6 is a diagram illustrating a setting example of hue regions in a hue space according to a third modification;

FIG. 7 is a block diagram of a functional configuration of an image processing apparatus according to a fifth modification;

FIG. 8 is a flowchart of a procedure of image processing according to the fifth modification;

FIG. 9 is a diagram illustrating an example of output color correspondence information according to a sixth modification;

FIG. 10 is a flowchart of a procedure of a first method of image processing according to the sixth modification; and

FIG. 11 is a flowchart of a procedure of a second method of the image processing according to the sixth modification.

### DETAILED DESCRIPTION OF THE PREFERRED EMBODIMENTS

Exemplary embodiments of an image processing apparatus, an image processing method, and a computer program product according to the present invention will be explained in detail below with reference to the accompanying drawings.

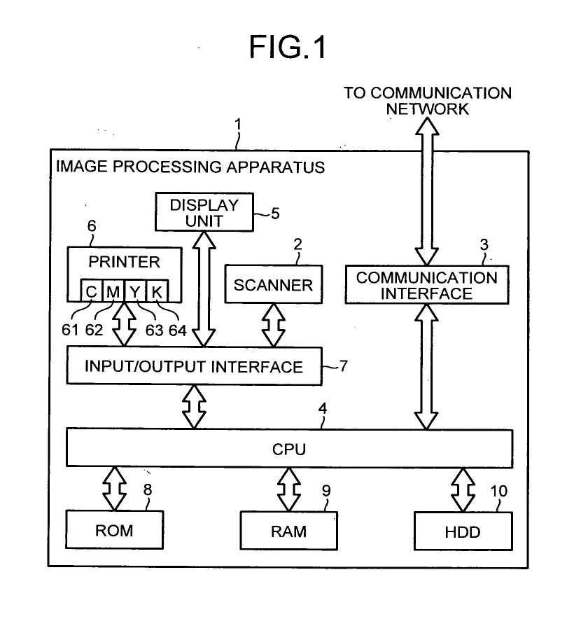

FIG. 1 is a block diagram of a hardware configuration of an image processing apparatus according to an embodiment of the present invention. In the following embodiment, an example will be explained in which the image processing apparatus is applied to a copying machine or a multifunction peripheral having a copying function.

As illustrated in FIG. 1, an image processing apparatus 1 of the embodiment includes, as principal elements of the hardware configuration, a scanner 2, a printer 6, a display unit 5, a communication interface 3, an input/output interface 7, a central processing unit (CPU) 4, a read only memory (ROM) 8, a random access memory (RAM) 9, and a hard disk drive (HDD) 10.

The scanner 2 is an engine that reads an original and outputs an image of the read original as input image data.

The communication interface 3 is an interface for receiving image data from external personal computers (PCs) (not illustrated) or the like via a communication network or the like.

The CPU 4 controls the entire image processing apparatus 1. According to the embodiment, the CPU 4 generates color-reduced image data, which contains fewer colors than the number of colors contained in input image data, from the input image data. Details of image processing that the CPU 4 performs by executing an image processing program will be described later.

The display unit 5 is a display device to be used by a user in displaying various image data on a screen. According to the embodiment, the display unit 5 displays color-reduced image data that contain fewer colors than the number of colors contained in the input image data.

The display unit 5 of the embodiment has a touch panel system and functions as an input device that allows a user to input various types of information, such as setting information, by touch operation. According to the embodiment, a user inputs the number n of output colors (n: an integer equal to or greater than 2) and a representative color from the display unit 5. The representative color is a secondary color that is made of two color materials by which a range of output colors to be used for generating color-reduced image data is determined.

The input/output interface 7 is an interface used for performing data communication when, for example, the display unit 5 performs various types of display operation, the printer 6 prints images, or various types of information are input by using the display unit 5 or the scanner 2.

The printer 6 is an engine that prints the generated color-reduced image data. The printer 6 includes color materials from 61 to 64 for C (cyan), M (magenta), Y (yellow), and K (black) that are used for printing the color-reduced image data.

The ROM 8 is a nonvolatile memory for storing the image processing program to be executed by the CPU 4. The RAM 9 is a volatile memory for loading the image processing program to be executed by the CPU 4 or temporarily storing data.

The HDD 10 is a storage medium for storing various types of data. According to the embodiment, the HDD 10 functions as an output color profile storage unit and stores therein an output color profile in advance, which will be described later. The HDD 10 also temporarily stores therein output-color correspondence information, which will be described later.

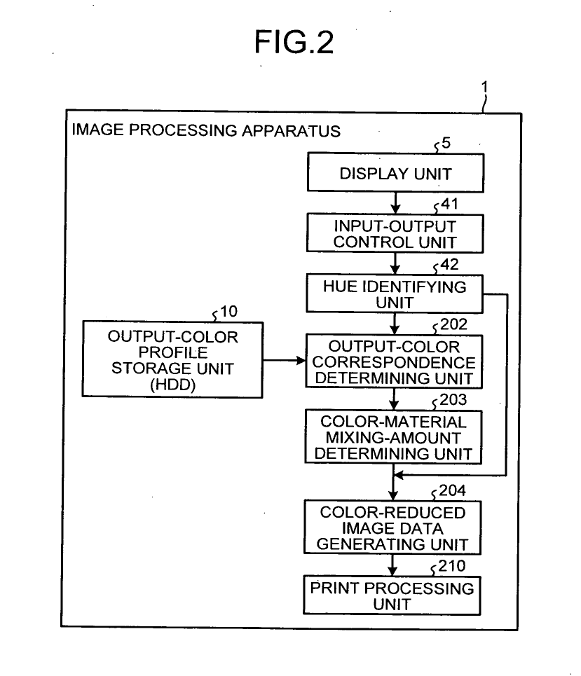

Details of the image processing performed by the CPU 4 will be explained below. FIG. 2 is a block diagram of a functional configuration of the image processing apparatus 1 according to the embodiment. As illustrated in FIG. 2, the image processing apparatus 1 of the embodiment includes, as principal elements, the display unit 5, an input-output control unit 41, a hue identifying unit 42, an output-color correspondence determining unit 202, a color-material mixing-amount determining unit 203, a color-reduced image data generating unit 204, a print processing unit 210, and the output color profile storage unit (HDD) 10. The display unit 5 is explained above, and therefore, the same explanation will not be repeated.

The input-output control unit 41 controls input of, for example, image data that is input via the display unit 5 and the input/output interface 7 or image data that is input from the scanner 2 or an external PC via the communication interface 3. Hereinafter, an image data that has been input is referred to as an input image data.

The input-output control unit 41 also controls display of various pictures and inputs on the display unit 5 via the input/output interface 7. According to the embodiment, the input-output control unit 41 receives, via the input/output interface 7, the number n of output colors and the representative color that are input by a user through the display unit 5. Furthermore, the input-output control unit 41 controls display of color-reduced image data, which is generated by the color-reduced image data generating unit 204, on the display unit 5 via the input/output interface 7.

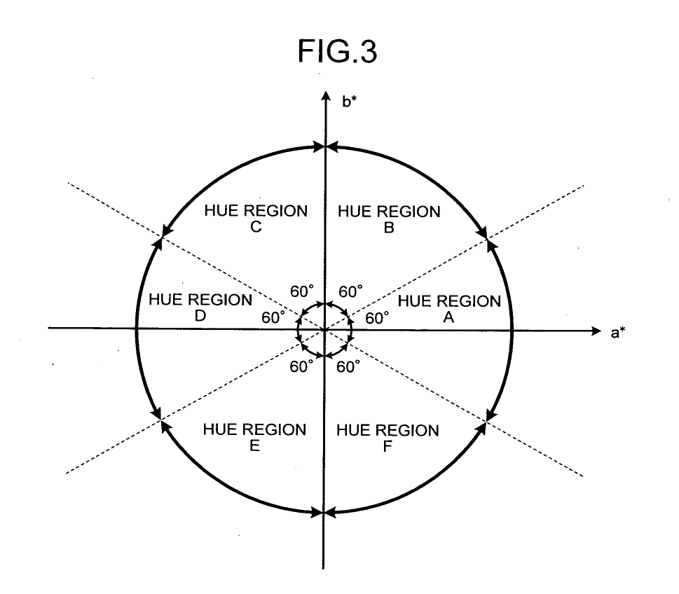

The hue identifying unit 42 sets, in a color space, the same number of hue regions as the input number n of output colors. The hue identifying unit 42 identifies to which hue region a hue of each pixel, contained in the input image data, belongs among a plurality of hue regions that are obtained by dividing the color space on the basis of hues. FIG. 3 is a diagram illustrating a setting example of the hue regions in a hue space. The hue regions are regions provided by dividing the color space by predetermined ranges.

In FIG. 3, an example is illustrated in which a user has input n=6 as the number n of output colors. The hue identifying unit 42 equally divides a hue angle (in the example of FIG. 3, the hue angle is 60°) on the a*b* plane in a color space based on the L*a*b* color representing system, so that n (i.e., 6) hue regions A to F are set in the color space on the basis of the hues. The angle that divides the hue angle can be determined depending on the number n of output colors.

Hereinafter, in the embodiment, the L*a*b* color space is used as a color space and n=6 hue regions A to F illustrated in FIG. 3 are used as an example to explain the L*a*b* color space. However, the color space is not limited to the L*a*b* color space, and the hue regions are not limited to the example illustrated in FIG. 3.

The hue identifying unit 42 identifies to which hue region a color of each pixel contained in the input image data (which is hereinafter referred to as an “input pixel”) belongs among the same number of hue regions as the number n of output colors, on the basis of the color of the input pixel. More specifically, the hue identifying unit 42 plots the color of each input pixel on the a*b* plane and identifies in which hue region the color of the input pixel is contained.

Referring back to FIG. 2, the output color profile storage unit (HDD) 10 stores in advance, for each of the number of the output colors, therein the output color profile that relates each of the hue regions and a mixing ratio of color materials which form an output color.

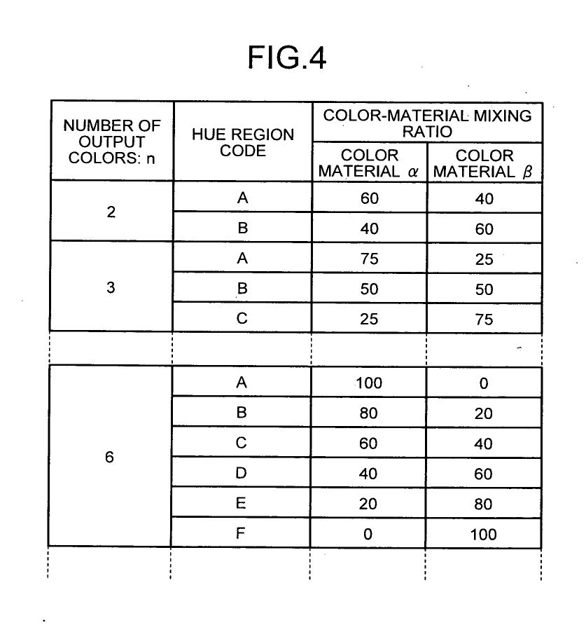

FIG. 4 is a diagram illustrating an example of a data structure of the output color profile stored in the output color profile storage unit 10. As illustrated in FIG. 4, in the output color profile, an output color associated with a hue region is indicated by a mixing ratio of color materials that form the output color, in a column for a color-material mixing ratio for each of n hue regions, where n is the number of output colors.

In the output color profile illustrated in FIG. 4, hue regions A to C in the case where the number n of output colors is 3 indicate three hue regions that are obtained by dividing the hue space by a hue angle into three equal regions. Hue regions A to F in the case where the number n of output colors is 6 indicate six hue regions that are obtained by dividing the hue space by a hue angle into six equal regions. The hue regions A to F in this case correspond to, for example, the six hue regions illustrated in FIG. 3.

Each of the hue regions is associated with an output color that is generated at a color-material mixing ratio indicated in the column for the color-material mixing ratio. For example, in the example of FIG. 4, when the number n of output colors is 6, an output color generated at a ratio of a color material α to a color material β being equal to 100:0 (i.e., an output color made of only one color material) is associated with the hue region A; an output color generated at a ratio of the color material α to the color material β being equal to 80:20 is associated with the hue region B; and an output color generated at a ratio of the color material α to the color material β being equal to 60:40 is associated with the hue region C. Similarly, an output color is associated with each of the subsequent hue regions D to F.

In determining output colors to be written in the output color profile, in order that a difference between colors that have been contained in an input image becomes maximally distinguishable by a difference between the color tones of the output colors in a color-reduced image, it is desirable that, within a range of colors that can be generated by the color materials, two of the output colors assigned to the respective hue regions be most distant from each other in the hue space and a hue angle made by the two colors take a largest possible value.

Referring back to FIG. 2, the output-color correspondence determining unit 202 associates, as output colors, colors that are made of mutually-different color materials, which form the representative color input by the user, which are fewer than the number n of output colors, and which are mixed at different mixing ratios, with the respective hue regions. According to the embodiment, the output-color correspondence determining unit 202 generates output-color correspondence information in which colors that are made of the color materials, which form the representative color input by the user, which are fewer than the number n of output colors, and which are mixed at different mixing ratios, are associated, as the output colors, with the respective hue regions that correspond to the number n of output colors in the output color profile.

More specifically, the output-color correspondence determining unit 202 generates the output-color correspondence information in which each of the color material α and the color material β indicated in the output color profile is associated with any of the color material 61 for C (cyan), the color material 62 for M (magenta), and the color material 63 for Y (yellow). The generated output-color correspondence information is temporarily stored in the HDD (the output color profile storage unit) 10. Examples of the output-color correspondence information include the following, when the number n of output colors is equal to three.

Hue Region A

Color material C:Color material M=75:25

Hue Region B

Color material C:Color material M=50:50

Hue Region C

Color material C:Color material M=25:75

The color-material mixing-amount determining unit 203 multiplies each value of the mixing ratio indicated in the output-color correspondence information by a predetermined coefficient to determine color-material mixing amounts, and generates color-material mixing information indicating the color-material mixing amounts in each hue region. Examples of the color-material mixing information include the following with a coefficient denoted by k.

Hue Region A

Color material C:Color material M=75k:25k

Hue Region B

Color material C:Color material M=50k:50k

Hue Region C

Color material C:Color material M=25k:75k The color-reduced image data generating unit 204 converts the color of each pixel contained in the input image data to an output color corresponding to the hue region identified by the hue identifying unit 42 to thereby generate color-reduced image data. The color-reduced image data generating unit 204 outputs the generated color-reduced image data together with the color-material mixing information to the print processing unit 210.

The print processing unit 210 controls the printer 6 so as to print the color-reduced image data, which is generated by the color-reduced image data generating unit 204, with the color-material mixing amounts indicated by the color-material mixing information.

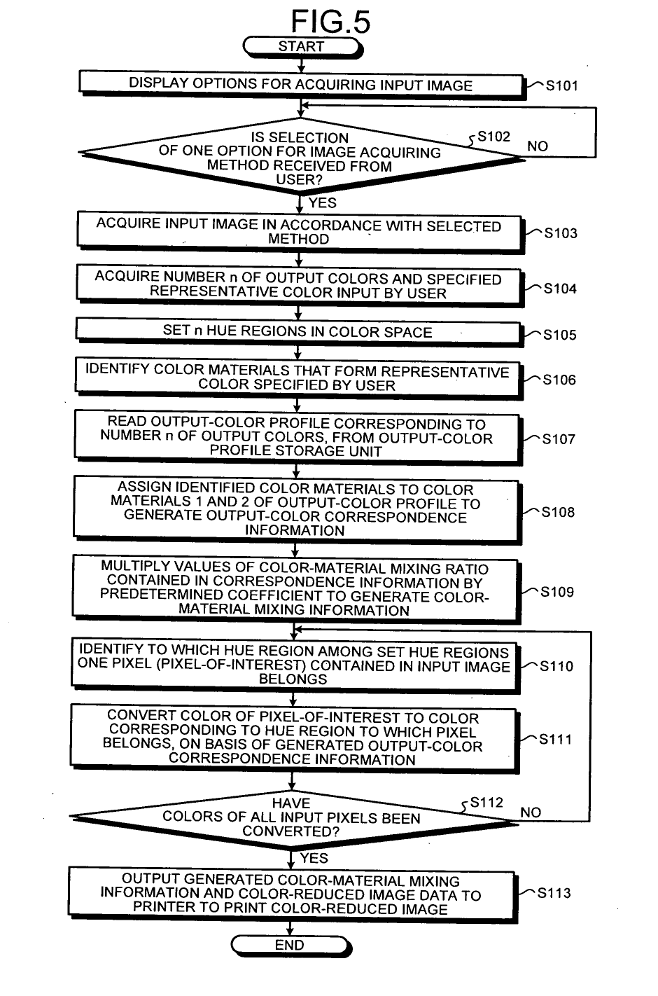

Image processing performed by the image processing apparatus 1 of the embodiment, which is configured as above, will be explained below. FIG. 5 is a flowchart of a procedure of the image processing according to the embodiment.

When a user turns on the image processing apparatus 1, the input-output control unit 41 displays options for acquiring input image data, such as to input an image by the scanner 2 or to receive an image from a PC via the communication interface 3, on the display unit 5 (Step S101). The input-output control unit 41 waits for the user to input selection of the image acquiring method that is selected from among the options via the screen on which the options are displayed (Step S102, NO at Step S102).

At Step S102, when receiving the selection of one of the options from the user (YES at Step S102), the input-output control unit 41 acquires input image data via the input/output interface 7 or the communication interface 3 in accordance with the selected option (Step S103).

The input-output control unit 41 then displays an input screen for inputting the number n of output colors and a representative color on the display unit 5, and acquires information on the number n of output colors and the representative color input by the user (Step S104).

The hue identifying unit 42 equally divides a hue angle in the color space that is based on the L*a*b* color representing system, on the basis of the number n of output colors input by the user to thereby set n hue regions A1 to An, as illustrated in FIG. 3 in which n=6 is set. (Step S105). The output-color correspondence determining unit 202 identifies color materials that form the representative color input by the user (Step S106). The output-color correspondence determining unit 202 reads the output color profile corresponding to the number n of output colors from the output color profile storage unit 10 (Step S107), and assigns the color materials identified at Step S106 to a color material 1 and a color material 2 contained in the read output color profile (see FIG. 4) to thereby generate the output-color correspondence information (Step S108).

The color-material mixing-amount determining unit 203 multiplies each value of the color-material mixing ratio contained in the output color profile by a predetermined coefficient to determine color-material mixing amounts, and generates the color-material mixing information indicating the color-material mixing amounts for each hue region (Step S109).

The hue identifying unit 42 focuses on an initial pixel contained in the input image data, for example, a pixel on the upper left corner of the input image (hereinafter, the pixel being focused on is referred to as a “pixel-of-interest”), and identifies to which hue region among the hue regions that are set at Step S105 a color of the pixel-of-interest belongs (Step S110). The color-reduced image data generating unit 204 converts the color of the pixel-of-interest to an output color corresponding to the hue region to which the pixel-of-interest belongs, on the basis of the output-color correspondence information generated at Step S108, to thereby generate color-reduced image data (Step S111).

The color-reduced image data generating unit 204 does not convert a black (achromatic) pixel, which is present on the lightness axis L* in the L*a*b* color space and therefore does not belong to any of the hue regions, to any colors, and generates color-reduced image data while maintaining the black pixel.

The color-reduced image data generating unit 204 determines whether colors of all of the input pixels have been converted to output colors (Step S112). When the colors of all of the input pixels have been converted to the output colors (YES at Step S112), the processing proceeds to Step S113. On the other hand, if there exists a color of any of the input pixels that has not been converted to an output color yet (NO at Step S112), the processing returns to Step S110, where the color-reduced image data generating unit 204 handles a next input pixel, e.g., a pixel adjacent to the current pixel-of-interest, as a new pixel-of-interest, and converts a color of the pixel-of-interest to an output color.

When the colors of all of the input pixels have been converted to the output colors and a color-reduced image is generated, the color-reduced image data generating unit 204 outputs the color-reduced image data together with the color-material mixing information generated at Step S110 to the print processing unit 210, and the print processing unit 210 controls the printer 6 to print the received color-reduced image data with the color-material mixing amounts specified by the color-material mixing information (Step S113).

As described above, the image processing apparatus 1 of the embodiment generates various output colors by changing a mixing ratio of two color materials that are used for generating a secondary color that is a representative color specified by a user. Therefore, a user can specify a larger number of output colors than the number of color materials (2 in the embodiment) used by the image processing apparatus 1 of the embodiment. Consequently, it is possible to generate a color-reduced image that can more clearly represent a difference between colors that have been contained in an input image when compared with a color-reduced image that is generated by the conventional method in which only two colors, i.e., one achromatic color and one chromatic color, are used.

First Modification

A first modification of the image processing apparatus 1 according to the embodiment will be explained below. In the first modification of the embodiment, a color-reduced image is structured such that a lightness axis in a color space is assumed as one hue region and an achromatic color on the lightness axis is associated with any of colors that are generated by mixing the two color materials at different mixing ratios.

More specifically, the hue identifying unit 42 divides a color space into the same number of hue regions as the number n of output colors on the basis of hues and lightness, and identifies to which hue region among a plurality of the hue regions set in the color space a hue and lightness of each pixel contained in image data belong.

According to the first modification, a color material for K (black) is not needed, so that it is possible to generate a color-reduced image with fewer color materials. Therefore, it is possible to reduce a running cost.

Second Modification

In a second modification of the image processing apparatus 1 according to the embodiment, the input-output control unit 41 not only acquires, from a user, the number n of output colors and the specified representative color, but also separately acquires hue angles of respective hue regions so that a hue space can be divided into n hue regions. The hue identifying unit 42 sets the hue regions based on the hue angles.

According to the second modification, in-addition to an equal division of the hue space by equal hue angles, a unequal division of the hue space by different hue angles is allowed, and, accordingly, it is possible to freely set a correspondence between a color of an input image and a color of a color-reduced image depending on user's preference.

Third Modification

In a third modification of the image processing apparatus 1 according to the embodiment, in addition to an input by a user to specify the number n of output colors and the representative color, the input-output control unit 41 also receives an input by a user to specify a chromatic conversion range, which is a hue range in which a color is converted to a chromatic output color. The hue identifying unit 42 divides a hue angle corresponding to the chromatic conversion range to provide n hue regions; associates black, as an output color, with a hue range other than the chromatic conversion range; and associates, as the output colors, chromatic colors that are generated by mixing, at different mixing ratios, color materials that are used for generating the representative color (the secondary color), with the respective n hue regions within the chromatic conversion range.

In the image processing apparatus 1 of the embodiment described above, chromatic colors, which are generated by mixing at different mixing ratios, the color materials that are used for generating the representative color (the secondary color), are associated with the respective hue regions that are set by dividing the whole color space. By contrast, according to the third modification, a range corresponding to a predetermined space in the color space is assumed as the chromatic conversion range, and the color-reduced image data generating unit 204 converts only colors in the chromatic conversion range, e.g., only warm colors in an input image, to red-based output colors that are generated by mixing color materials for M (magenta) and Y (yellow) at different mixing ratios, and converts colors in a range other than the chromatic color conversion range, i.e., colors other than the warm colors, to black that is an achromatic color. Therefore, it is possible to generate a color-reduced image in which only portions that have been represented by the warm colors in an input image are intensified.

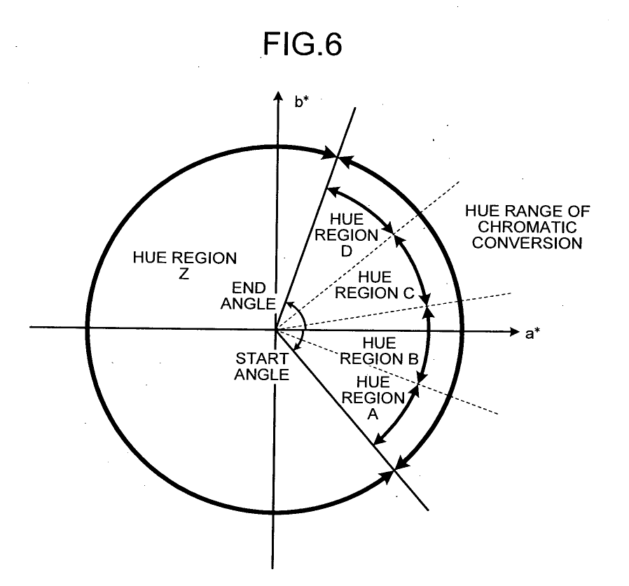

More specifically, as illustrated in FIG. 6, a user inputs the hue range of chromatic conversion by specifying a hue angle (a start angle) and a hue angle (an end angle) that respectively indicate start and end of the chromatic conversion range, as angles from the a* axis in the L*a*b* color space, and the input-output control unit 41 receives the input of the chromatic conversion range.

When, for example, the number n of output colors is 4, the hue identifying unit 42 sets four hue regions A to D in the chromatic conversion range and sets a hue region Z to the whole range other than the chromatic color conversion range.

Accordingly, when a hue region to which a pixel being focused on (i.e., a pixel-of-interest) belongs is the hue region Z, the color-reduced image data generating unit 204 converts a color of the pixel-of-interest to black, and, when a hue region to which the pixel-of-interest belongs is other than the hue region Z, the color-reduced image data generating unit 204 converts the color of the pixel-of-interest to a chromatic color on the basis of the output-color correspondence information generated by the output-color correspondence determining unit 202.

Therefore, according to the third modification, it is possible to intensify, in a color-reduced image, only portions that have been represented by specific sorts of colors in an input image. As a result, it is possible to generate a color-reduced image that can meet various needs of users.

Fourth Modification

In a fourth modification of the image processing apparatus 1 according to the embodiment, the color-material mixing-amount determining unit 203 generates color-material mixing information so that a sum of amounts of color materials used for generating an output color (hereinafter, the amounts are described as “mixing amounts”) does not exceed an amount of any one color material used for generating a monochrome by only the one of the color materials. More specifically, information on an amount of a single color material to be used for generating a monochrome by only the single color material (hereinafter, the amount is described as “an amount of use for a monochrome”) is stored in a memory or the like for each of the color materials, and the color-material mixing-amount determining unit 203 generates the color-material mixing information so that a sum of the mixing amounts of the color materials does not exceed the amount of use for a monochrome.

Therefore, according to the fourth modification, it is possible to prevent an increase in total consumption of the color materials due to use of two color materials, compared with a structure in which a color-reduced image is generated by using one chromatic color made of only one color material and one achromatic color being either black or white. Consequently, it is possible to prevent an increase in a running cost.

Even when the color-material mixing information is generated so that an amount of each of color materials used for generating an output color does not exceed an amount of any one color material used for generating a monochrome by only the one of the color materials, it is possible to achieve the same advantages as described above.

Fifth Modification

In a fifth modification of the image processing apparatus 1 according to the embodiment, when the output-color correspondence information is generated, an output color is determined directly from the number n of output colors and the representative color, which are input by a user, without using the output color profile. Hereinafter, “to determine an output color directly from the number n of output colors and the representative color, which are input by a user, without using the output color profile” is described as “to dynamically determine an output color”.

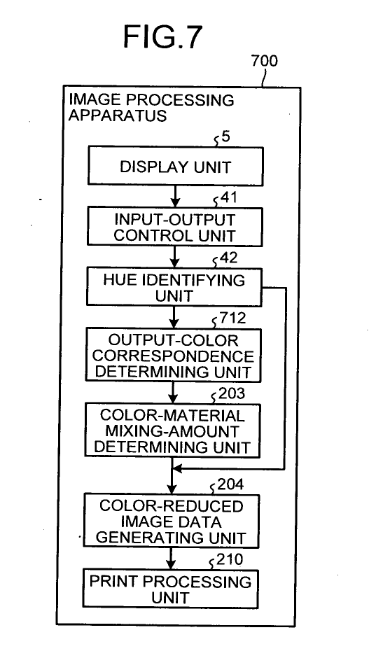

FIG. 7 is a block diagram of a functional configuration of an image processing apparatus 700 according to the fifth modification. The image processing apparatus 700 according to the fifth modification is different from the image processing apparatus 1 of the above embodiment in that it does not include the output color profile storage unit 10. The other configurations of the image processing apparatus 700 are the same as those of the image processing apparatus 1 of the above embodiment.

According to the fourth modification, an output-color correspondence determining unit 712 dynamically determines an output color. More specifically, the output-color correspondence determining unit 712 generates output-color correspondence information which, using the number n of output colors and the representative color that are input by the user, makes a relation between a color that is generated by changing the mixing ratio of a plurality of color materials that form the input representative color and an output color.

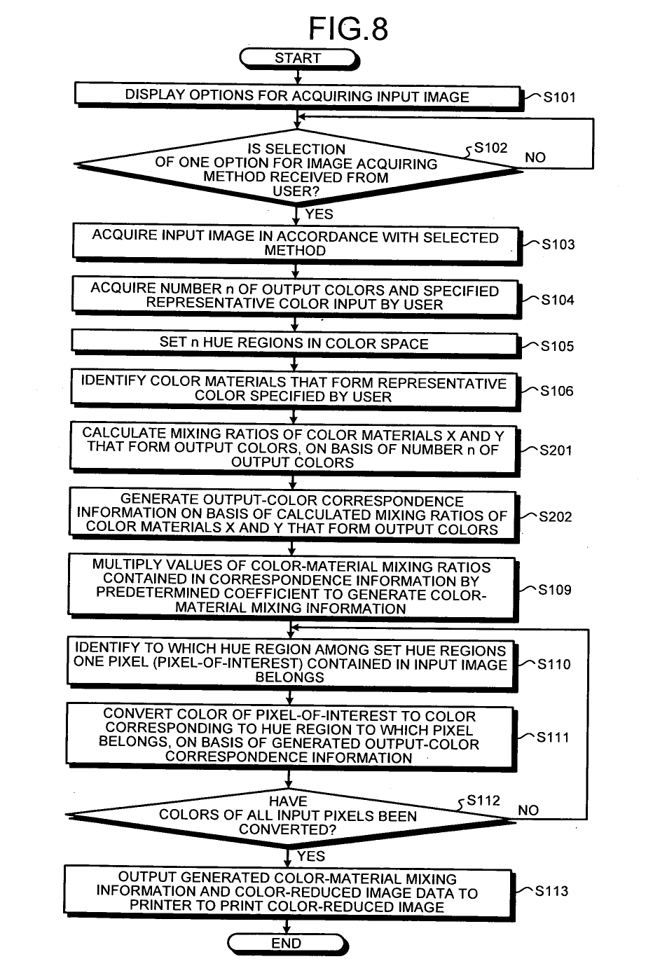

FIG. 8 is a flowchart of a procedure of image processing according to the fifth modification. The image processing according the fifth modification can be implemented by replacing Steps S107 and S108 in the flowchart of FIG. 5 described in the above embodiment with Steps S201 and S202 in the flowchart of FIG. 8.

More specifically, the output-color correspondence determining unit 712 calculates mixing ratios of the color materials such as a color material X and a color material Y, for generating output colors that are to be assigned to respective hue regions, on the basis of the color materials identified at Step S106 and the number n of output colors (Step S201), and generates the output-color correspondence information on the basis of a calculation result (Step S202).

As the calculation performed at Step S201 of FIG. 8, assuming that n hue regions are represented by A1 to An and the color materials determined from the representative color are represented by a color material P and a color material Q, a mixing ratio of the color materials P and Q that form an output color to be associated with a hue region Am (1≦m≦n) is determined by the following Equation.

Color material P:Color material Q=(m−1)/(n−1):(n−m)/(n−1)

In this case, an output color for the hue region A1 (m=1) is generated by only the color material Q, an output color for the hue region n (m=n) is generated by only the color material P, and output colors for the hue regions 2 to (n−1) are generated as intermediate colors between the color materials P and Q.

As described above, according to the fifth modification, because an output color is dynamically determined, since there is no need to provide the output color profile storage unit 10, the image forming apparatus can be configured more simply and at a lower cost. Furthermore, it is not necessary to prepare the output-color profile in advance in generating the output color correspondence information, design loads can be reduced.

Sixth Modification

In a sixth modification of the embodiment, when a specific output color, which is difficult to be distinguished in color-reduced image data (hereinafter, this output color is described as “a specific color”) is contained in the output-color correspondence information determined by the output-color correspondence determining unit 712 of the above fifth modification, the specific color is changed to a different output color.

More specifically, for example, a list of mixing amounts of color materials that form the specific colors is stored in advance in a memory or the like, and the color-material mixing-amount determining unit 203 determines whether the output-color correspondence information contains the specific color. When the specific color is contained, the specific color is changed to a different output color by, for example, either one of the following two methods.

As a first method of changing the specific color to a different output color, it is possible to mix a predetermined amount of a predetermined color material (hereinafter, described as “an additional color material”) such as a color material for K (black) with the specific color in order to decrease lightness so that use of the specific color can be avoided. In this case, the predetermined additional color material and the mixing amount of the additional color material are provided to the color-reduced image data generating unit 204, and the output-color correspondence determining unit 712 generates output-color correspondence information by adding information indicating whether or not an output color is the specific color.

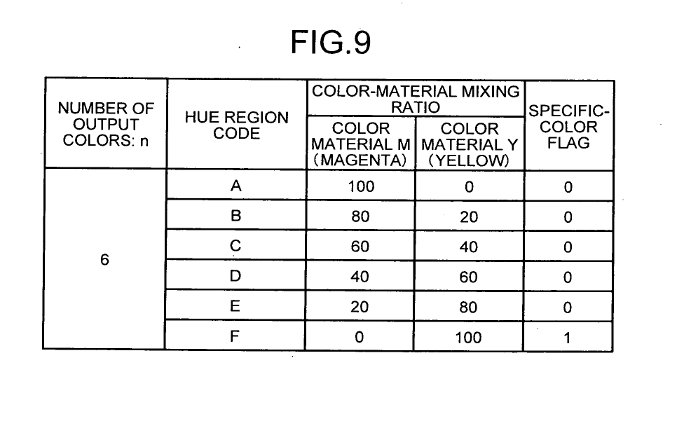

FIG. 9 illustrates an example of the output-color correspondence information. The output-color correspondence information illustrated in FIG. 9 indicates a case in which the number n of output colors is 6 and output colors are represented by mixing ratios of color materials M (magenta) and Y (yellow). In a column on the right side of the column for a color-material mixing ratio, a specific-color flag that indicates whether or not an output color is a specific color is added. When generating the color-reduced image data, the color-reduced image data generating unit 204 can mix an additional color material with an output color being the specific color on the basis of the specific-color flag.

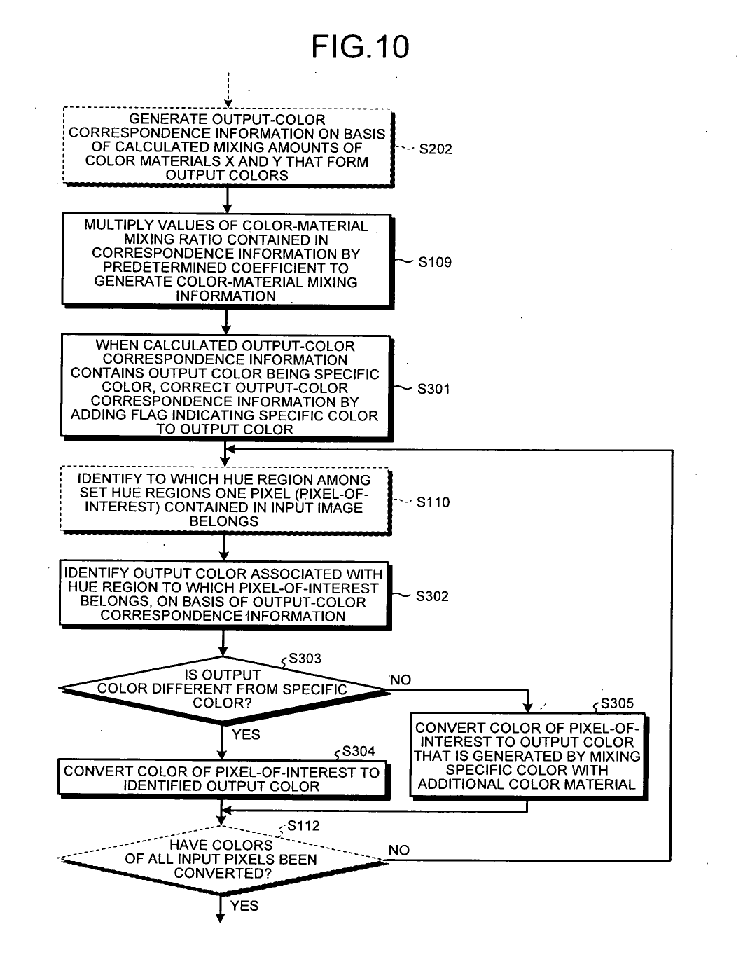

FIG. 10 is a flowchart of a procedure of the first method of image processing according to the sixth modification. The first method can be implemented by adding Step S301 of FIG. 10 after the processing at Step S109 of FIG. 8 and replacing Step S111 of FIG. 8 with Steps S302 to S305 of FIG. 10. The operating procedure according to the sixth modification will be described below along with a flow diagram of FIG. 10.

When the output-color correspondence information calculated at Step S202 of FIG. 8 contains an output color being a specific color, the output-color correspondence determining unit 712 corrects the output-color correspondence information by adding a flag indicating the specific color to the output color (Step S301). The hue identifying unit 42 then identifies to which hue region among the hue regions set at Step S105 of FIG. 8 a pixel (a pixel-of-interest) contained in input image data belongs (Step S110 of FIG. 8).

The color-reduced image data generating unit 204 identifies an output color associated with the hue region to which the pixel-of-interest belongs, on the basis of the output-color correspondence information (Step S302). The color-reduced image data generating unit 204 determines whether or not the output color is a color other than the specific color (Step S303). When the output color is other than the specific color (YES at Step S303), the color-reduced image data generating unit 204 converts the color of the pixel-of-interest to the output color identified at Step S302 (Step S304). On the other hand, when the output color is the specific color (NO at Step S303), the color-reduced image data generating unit 204 converts the color of the pixel-of-interest to an output color that is generated by mixing the specific color with a predetermined amount of a predetermined additional color material (Step S305).

As a second method of changing the specific color to a different output color, it is possible to avoid use of the specific color in the following manner: when any of output colors is the specific color, mixing amounts of the color materials are re-calculated so that the number of the output colors is increased by one, and the specific color is excluded from the output colors so that the remaining output colors are used as actual output colors.

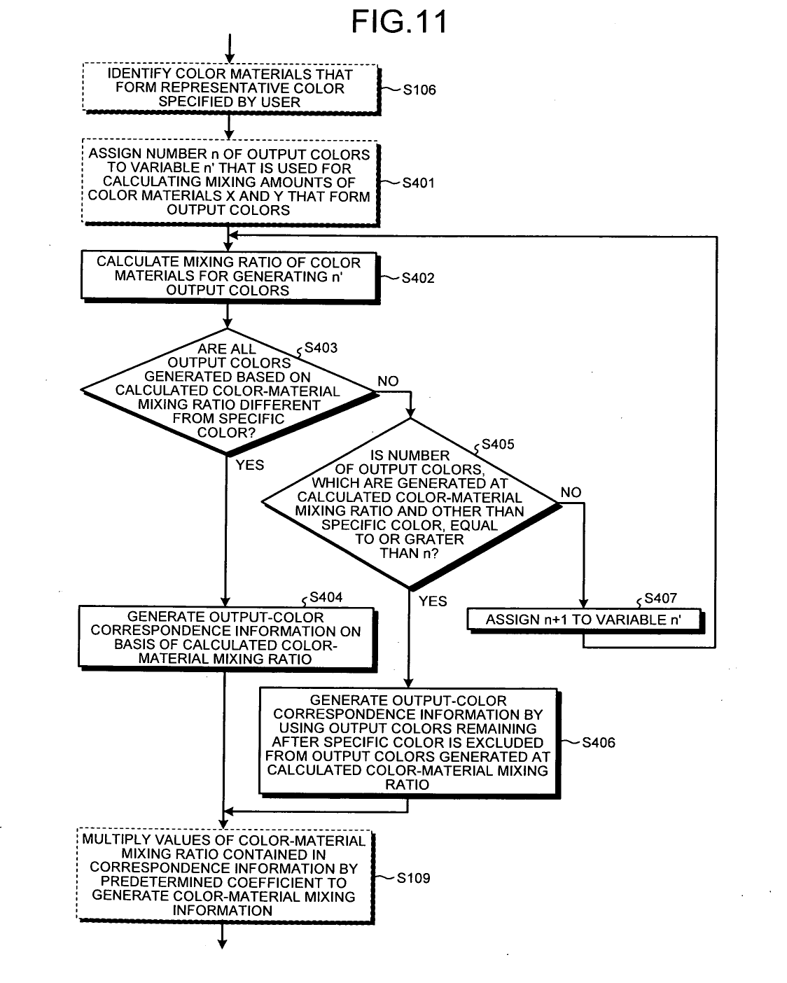

FIG. 11 is a flowchart of a procedure of the second method of the image processing according to the sixth modification. The second method can be implemented by, for example, replacing Steps S201 and S202 of FIG. 8 with Steps S401 to S407 of FIG. 11. The operating procedure will be described below along with an operational flow of FIG. 11. In the following explanation, the hue regions set at Step S105 of FIG. 8 are represented by A1 to An, and the color materials identified at Step S106 of FIG. 8 are represented by a color material X and a color material Y.

The output-color correspondence determining unit 712 assigns n to a variable n′ that is used for calculating amounts of the color materials (Step S401), and calculates a mixing ratio of the color materials used for generating n′ output colors (Step S402). The calculation is made by assuming a mixing ratio of the color material X and the color material Y such that the color material X: the color material Y=(m−1)/(n′−1):(n′−m)/(n′−1).

The output-color correspondence determining unit 712 determines whether all of the n′ output colors that are generated on the basis of the color-material mixing amounts calculated at Step S402 are other than the specific color (Step S403). When all of the output colors are other than the specific color (YES at Step S403), the output-color correspondence determining unit 712 generates output-color correspondence information on the basis of the color-material mixing amounts calculated at Step S402 (Step S404).

On the other hand, when the specific color is included (NO at Step S403), the output-color correspondence determining unit 712 determines whether the number of the output colors other than the specific color is larger than or equal to n (Step S405). When the number of the output colors is larger than or equal to n (YES at Step S405), the output-color correspondence determining unit 712 generates the output-color correspondence information by using output colors remaining after the specific color is excluded from the output colors that have been generated at the color-material mixing ratio calculated at Step S402 (Step S406). On the other hand, when the number of the output colors is smaller than n (NO at Step S405), the output-color correspondence determining unit 712 assigns (n+1) to the variable n′ (Step S407), and returns to Step S402 to calculate a mixing ratio of the color materials for generating output colors so that the number of the output colors can be increased by one.

As described above, according to the sixth modification, it is possible to avoid using a color that is difficult to be distinguished in a color-reduced image data such as plain yellow contained in a color-reduced image printed on a white paper. Therefore, it makes more clearly visible, in a color-reduced image, a difference between colors that have been contained in an input image.

Seventh Modification

In a seventh modification of the image processing apparatus 1 according to the embodiment, the output-color correspondence determining unit 202 can generate output-color correspondence information so that users who have different color vision characteristics can distinguish a difference between color tones of the output colors to be used.

Therefore, according to the seventh modification, it is possible to generate a color-reduced image to make a difference between colors of portions that have been contained in an input image distinguishable for users having different color vision characteristics in the color-reduced image.

Eighth Modification

In an eighth modification of the image processing apparatus 1 according to the embodiment, the input-output control unit 41 acquires, as a representative color, a tertiary color that is generated by mixing three color materials from a user. In this case, the output-color correspondence determining unit 202 generates output-color correspondence information in which an output color represented by a mixing ratio of three color materials is associated with each of the hue regions. Furthermore, mixing ratios of the three color materials are set in the column for a color-material mixing ratio in the output color profile stored in the output color profile storage unit 10.

Therefore, according to the eighth modification, it is possible to more precisely represent a difference between colors that have been contained in input image data in a color-reduced image.

As described above, according to the embodiment, various output colors are generated by changing a mixing ratio of two color materials that form a secondary color being a representative color specified by a user. Therefore, it is possible to allow the user to specify the larger number of output colors than the number of color materials (2 in the embodiment) used by the image processing apparatus 1. As a result, it is possible to more clearly represent, in a color-reduced image, a difference between colors that have been contained in an input image than in a color-reduced image generated by the conventional method in which only two colors, i.e., one achromatic color and one chromatic color, are used.

Furthermore, a hue space is divided into a first hue range, in which colors are converted to an achromatic color, and a second hue range, in which colors are converted to chromatic colors; the first hue range in which colors are converted to chromatic colors (the hue region for chromatic conversion) is divided into a plurality of hue regions; and colors in each of the hue regions within the chromatic conversion range are converted to different output colors that are made by changing mixing amounts of two color materials. Therefore, it is possible to convert a portion, which is in a color based on a specific color in an input image, to a chromatic color in a color-reduced image so that the portion can be intensified. As a result, it is possible to generate a color-reduced image that meets various needs of users.

The image processing program executed by the image processing apparatuses 1 and 700 of the embodiment and the modifications is provided by being installed in the ROM 8 in advance; however, the present invention is not limited to this example. The image processing program to be executed by the image processing apparatuses 1 and 700 of the embodiment and the modifications may be provided as a computer program product by being recorded in a computer-readable recording medium, such as a CD-ROM, a flexible disk (FD), a CD-R, or a Digital Versatile Disk (DVD), in an installable or executable format.

The image processing program to be executed by the image processing apparatuses 1 and 700 of the embodiment and the modifications may be stored in a computer connected to a network, such as the Internet, and provided by being downloaded via the network. The image processing program to be executed by the image processing apparatuses 1 and 700 of the embodiment and the modifications may be provided or distributed via a network, such as the Internet.

The image processing program to be executed by the image processing apparatuses 1 and 700 of the embodiment and the modifications have a module structure made of the above-mentioned units (the input-output control unit 41, the hue identifying unit 42, the output-color correspondence determining units 202 and 712, the color-material mixing-amount determining unit 203, the color-reduced image-data generating unit 204, and the print processing unit 210). As actual hardware, the CPU 4 reads the image processing program from the recording medium and executes it to load the above units on the main memory, such as the RAM 9, thereby generating the input-output control unit 41, the hue identifying unit 42, the output-color correspondence determining units 202 and 712, the color-material mixing-amount determining unit 203, the color-reduced image-data generating unit 204, and the print processing unit 210 on the main memory.

In the embodiment described above, an example has been explained in which the image processing apparatus of the present invention is applied to a multifunction peripheral that has at least two functions from among a copying function, a printer function, a scanner function, and a facsimile function. However, the present invention can be applied to any image forming apparatuses, such as a copying machine, a printer, and a facsimile machine.

Furthermore, according to the embodiment, an example has been explained in which the image processing apparatus of the present invention is applied to an image forming apparatus, such as a copying machine. However, the image processing apparatus of the present invention can be applied to an information processing apparatus such as an ordinary computer.

According to one aspect of the present invention, it is possible to structure color-reduced image data by using the greater number of colors than the number of color materials to be used for generating the color-reduced image data. Therefore, it is possible to more clearly distinguish, in the color-reduced image data, a difference between colors that have been contained in input image data.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An image processing apparatus that generates color-reduced image data that contains fewer colors than the number of colors contained in input image data, the image processing apparatus comprising:
a hue identifying unit that identifies to which hue region among a plurality of hue regions, which are provided by dividing a color space by hues, a hue of each pixel contained in the image data belongs;
an output-color correspondence determining unit that determines correspondence between the hue regions and respective output colors that are used for generating the color-reduced image data; and
a color-reduced image data generating unit that converts a color of each pixel contained in the image data to an output color corresponding to the hue region identified by the hue identifying unit, wherein
the output-color correspondence determining unit associates, as the output colors, colors that are generated by mixing mutually-different color materials at different mixing ratios with the respective hue regions, the color materials forming a representative color that determines a range of the output colors and being fewer than a number of the output colors.

2. The image processing apparatus according to claim 1, further comprising:
an input receiving unit that receives input of the number of the output colors and the representative color from a user, wherein
the hue identifying unit sets the same number of hue regions as the input number of the output colors in the color space, and
the output-color correspondence determining unit generates output-color correspondence information, in which colors that are generated by mixing mutually-different color materials at different mixing ratios, the color materials forming the input representative color, are associated, as the output colors, with the respective hue regions.

3. The image processing apparatus according to claim 2, further comprising:
a storage unit that stores therein output color profile, in which each of the hue regions and a mixing ratio of the color materials that form the output colors are associated with each other for each of the number of the output colors, wherein
the output-color correspondence determining unit generates output-color correspondence information in which colors that are generated by mixing the color materials at different mixing ratios, the color materials forming the input representative color, are associated with the respective hue regions that correspond to the input number of the output colors in the output color profile.

4. The image processing apparatus according to claim 2, wherein
the output-color correspondence determining unit generates output-color correspondence information, in which two of the output colors form a largest hue angle in the color space within a range of colors that are generated by mixing the color materials at different mixing ratios.

5. The image processing apparatus according to claim 2, wherein
the output-color correspondence determining unit generates output-color correspondence information, in which colors that are generated by mixing the color materials, which form the input representative color, and that are determined directly from the input number of the output colors and the input representative color are associated, as the output colors, with the respective hue regions.

6. The image processing apparatus according to claim 5, wherein
the output-color correspondence determining unit generates the output-color correspondence information without using a predetermined specific color among colors that are generated by mixing the color materials at different mixing ratios.

7. The image processing apparatus according to claim 5, wherein
the output-color correspondence determining unit generates the output-color correspondence information to make a difference between color tones of the output colors distinguishable for users having different color vision characteristics.

8. The image processing apparatus according to claim 5, wherein
when the output-color correspondence information indicates that the output colors include a specific color, the color-reduced image data generating unit generates the color-reduced image data by mixing the specific color with a predetermined amount of a predetermined color material so that the specific color is not included in the output colors.

9. The image processing apparatus according to claim 1, wherein
the color space is divided into the hue regions on the basis of hues and lightness, and
the hue identifying unit identifies to which hue region among the hue regions provided in the color space a hue and lightness of each pixel contained in the image data belong.

10. The image processing apparatus according to claim 2, wherein
the input receiving unit receives input of hue angles from the user, and
the hue identifying unit sets the same number of hue regions as the input number of the output colors in the color space on the basis of the input hue angles.

11. The image processing apparatus according to claim 2, wherein
the hue regions are provided in a range corresponding to a predetermined space in the color space, and
the color-reduced image data generating unit generates the color-reduced image data by converting chromatic colors contained in the input image data in such a manner that a chromatic color that is out of the range corresponding to the predetermined space is converted to an achromatic color and a chromatic color that is within the range corresponding to the predetermined space is converted to any of chromatic colors, which are generated by mixing two or more different color materials at different mixing ratios, in accordance with a hue region to which the chromatic color to be converted belongs.

12. The image processing apparatus according to claim 2, wherein
the input receiving unit receives, from a user, input of a chromatic conversion range, which is a hue range in which a color is converted to a chromatic output color, and
the hue identifying unit divides a hue angle corresponding to the chromatic conversion range into angles so that the same number of hue regions as the input number of the output colors are provided, associates a black output color with a hue range other than the chromatic conversion range, and associates, as the output colors, colors that are generated by mixing the color materials at different mixing ratios, the color material forming the input representative color, with the respective hue regions within the chromatic conversion range.

13. The image processing apparatus according to claim 2, wherein
the input receiving unit receives, from a user, input of a tertiary color as the representative color, the tertiary color being generated by mixing three colors, and
the output-color correspondence determining unit generates output-color correspondence information in which colors that are made by mixing three mutually-different color materials at different mixing ratios, the color materials forming the input tertiary color, with the respective hue regions.

14. The image processing apparatus according to claim 1, further comprising:
a color-material mixing-amount determining unit that determines color-material mixing amounts that are obtained by multiplying each value of the mixing ratio contained in the output-color correspondence information by a predetermined coefficient, wherein
the output-color correspondence determining unit relates, as the output colors, colors that are made of color materials, with the color-material mixing amounts, to the respective hue regions.

15. The image processing apparatus according to claim 14, wherein
the color-material mixing-amount determining unit determines the color-material mixing amounts so that a color-material mixing amount of each of the color materials does not exceed an amount of use that is used for a monochrome.

16. An image processing method implemented by an image processing apparatus that generates color-reduced image data that contains fewer colors than the number of colors contained in input image data, the image processing method comprising:
identifying to which hue region among a plurality of hue regions, which are provided by dividing a color space by hues, a hue of each pixel contained in the image data belongs;
determining correspondence between the hue regions and respective output colors that are used for generating the color-reduced image data; and
converting a color of each pixel contained in the image data to an output color corresponding to the hue region identified by the hue identifying unit, wherein
the determining includes associating, as the output colors, colors that are made by mixing mutually-different color materials at different mixing ratios with the respective hue regions, the color materials forming a representative color that determines a range of the output colors and being fewer than the number of the output colors.

17. A computer program product comprising a non-transitory computer-readable medium having computer-readable program codes recorded in the medium, the program codes when executed causing a computer to execute:
identifying to which hue region among a plurality of hue regions, which are provided by dividing a color space by hues, a hue of each pixel contained in the image data belongs;
determining correspondence between the hue regions and respective output colors that are used for generating the color-reduced image data; and
converting a color of each pixel contained in the image data to an output color corresponding to the hue region identified by the hue identifying unit, wherein
the determining includes associating, as the output colors, colors that are made by mixing mutually-different color materials at different mixing ratios with the respective hue regions, the color materials forming a representative color that determines a range of the output colors and being fewer than the number of the output colors.
